(19) United States
(12) Patent Application Publication
(10) Pub. No.: US 2024/0395732 A1
(43) Pub. Date: Nov. 28, 2024

(54) METHOD OF MANUFACTURING A SEMICONDUCTOR DEVICE

(71) Applicant: SK hynix Inc., Icheon-si Gyeonggi-do (KR)

(72) Inventors: Seok Min CHOI, Icheon-si Gyeonggi-do (KR); Jung Shik JANG, Icheon-si Gyeonggi-do (KR); Rho Gyu KWAK, Icheon-si Gyeonggi-do (KR); In Su PARK, Icheon-si Gyeonggi-do (KR); Won Geun CHOI, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 18/478,798

(22) Filed: Sep. 29, 2023

(30) Foreign Application Priority Data
May 22, 2023 (KR) 10-2023-0065809

(51) Int. Cl. H01L 23/00

(52) U.S. Cl. CPC H01L 23/562

(57) ABSTRACT

In a method of manufacturing a semiconductor device, an additional, induced-stress-limiting structure may be provided on a surface, which opposes stress that can be induced in a semiconductor device during its manufacturing processes. Such a stress compensation layer may be formed on a surface to compensate a stress applied to the rest of structure.

### CROSS-REFERENCES TO RELATED APPLICATION

The present application claims priority under 35 U.S.C. § 119(a) to Korean application number 10-2023-0065809, filed on May 22, 2023, in the Korean Intellectual Property Office, which is incorporated herein by reference in its entirety.

### BACKGROUND

### 1. Technical Field

Various embodiments generally relate to a method of manufacturing a semiconductor device, which is configured to prevent or reduce a warpage of the device during fabricating processes.

### 2. Related Art

In order to provide a semiconductor device with a small size and a high density, a semiconductor device may stack multiple devices in the same “foot print.” Such a three-dimensional (3D) vertical structure may be used to provide a plurality of memory devices, each device having multiple cells.

A 3D semiconductor device having a vertical structure can warp during fabrication.

When a semiconductor warps or bends, the warpage prevents a wafer from being loaded into fabrication apparatuses. Subsequent fabrication processes may thus be impossible.

### SUMMARY

Example embodiments may provide a method of manufacturing a semiconductor device, which t may provide compensation for mechanical stress and strain caused by compressive or tensile forces applied to a semiconductor device during fabrication.

There is provided a method of manufacturing a semiconductor device wherein a structure of a semiconductor device may have first and second opposing surfaces. A compensation layer is formed on the second surface to compensate for stress applied to or within the structure. Stress and resultant strain may be reduced.

### BRIEF DESCRIPTION OF THE DRAWINGS

The above and another aspects, features and advantages

of the subject matter of the present disclosure will be more clearly understood from the following detailed description taken in conjunction with the accompanying drawings, in which:

FIGS. 1A and 1B are perspective views illustrating a multi-layer semiconductor structure and a stress compensation layer in accordance with example embodiments;

FIG. 1C is a vertical cross section of the structure shown in FIG. 1A and FIG. 1B.

FIG. 2 is a flow chart illustrating steps of a method of manufacturing a semiconductor device in accordance with example embodiments;

FIG. 3 is a perspective view a multi-layer semiconductor structure illustrating step S10 of FIG. 2, for forming a buffer layer before removing a second layer;

FIG. 4 is a view perspective view of a multi-layer semiconductor structure, also illustrating step S10 for forming a buffer layer after removing a second layer;

FIG. 5 is a perspective view of a multi-layer semiconductor structure, illustrating step S20 of FIG. 2 for forming a compensation layer in accordance with example embodiments;

FIGS. 6A and 6B are perspective views illustrating step S30 of FIG. 2 for forming a support trench in accordance with example embodiments;

FIGS. 7A and 7B are perspective views illustrating step S40 of FIG. 2 for forming a support with a first supporting portion in accordance with example embodiments;

FIG. 8 is a plan or horizontal cross-sectional view illustrating a slit trench on a front surface of a structure with a compensation layer and a first supporting portion on a second surface of the structure in accordance with example embodiments;

FIG. 9 is a view illustrating a slant support in accordance with example embodiments;

FIG. 10 is a view illustrating a support in accordance with example embodiments;

FIG. 11 is a view illustrating a size change caused by a warpage;

FIGS. 12A and 12B are perspective views illustrating step S50 of FIG. 2, for removing a buffer layer;

FIGS. 13, 14A and 14B are views illustrating a structure and an integrated circuit with a memory cell structure layer at a second layer by a following process after removing a buffer layer;

FIGS. 15A and 15B are views illustrating an integrated circuit and a structure with a slit in accordance with example embodiments; and

FIG. 16 is a view illustrating a structure after removing a compensation layer and an integrated circuit with a slit.

### DETAILED DESCRIPTION

As used herein, the term “stress” refers to compressive or tensile force exerted on an object, either of which may cause an object to deform by compaction or elongation respectively. “Strain” refers to a displacement between particles of an object subjected to stress. If there is an increase in an object's length, the object's strain is tensile. If there is reduction or compression of the object's size, the object's strain is compressive.

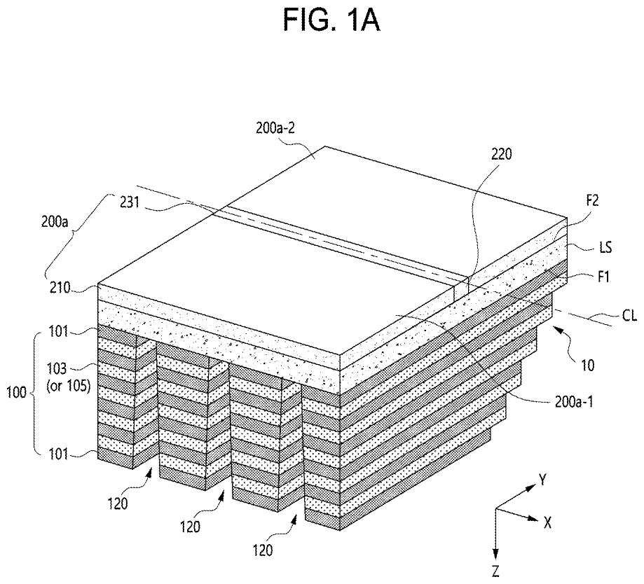

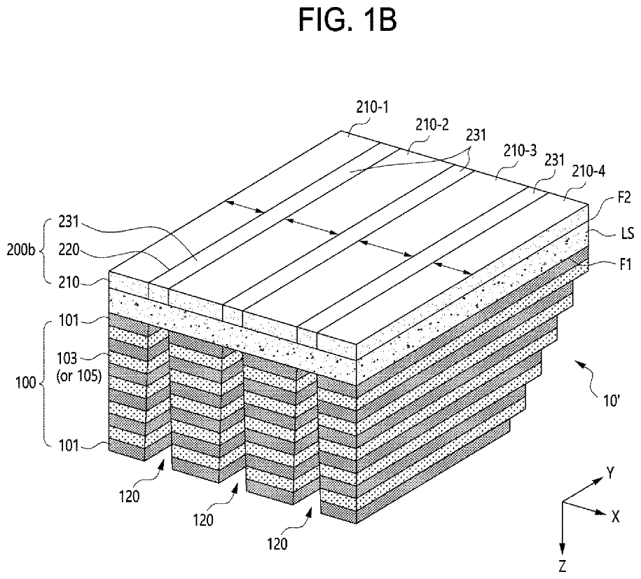

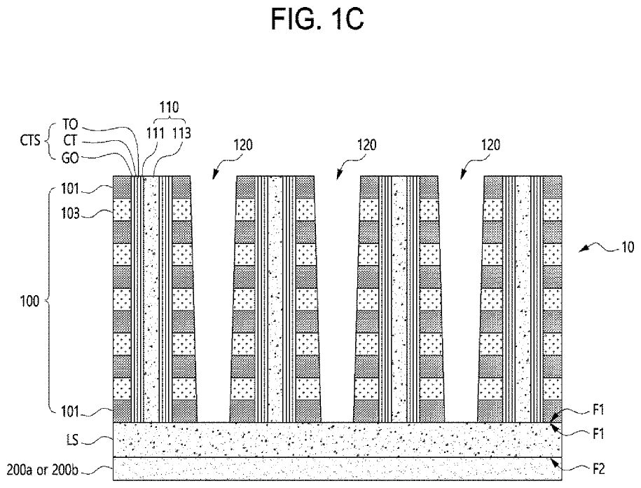

FIGS. 1A and 1B are perspective views of a stress-reducing and strain-reducing compensation structure 200a (in FIG. 1A) or 200b (in FIG. 1B) which is attached to a bottom surface F2 of a lower structure, LS, which is formed and attached to the “bottom” surface F1, of an integrated circuit 10, which may be made of several separate integrated circuit layers, those layers being collectively identified in the figures by reference numeral 100.

The compensation structures 200a and 200b depicted in FIGS. 1A-1C may include a compensation layer 210 and a first supporting portion 231. In FIG. 1A, a single, first supporting portion 231 is located between two compensation structure segments identified by reference numerals 200a-1 and 200a-2. In FIG. 1B, which shows a different semiconductor device 10′ multiple first compensation structures 231 are located directly above slits 120 formed through the layers 100 and evenly spaced between adjacent multiple compensation layers 210-1, 210-2, 210-3 and 210-4. Regardless of how many compensation layers 210 there may be and their orientation relative to slits 120 formed in the layers 100, the compensation layers 210 may be formed on a “bottom” surface F2 of the structure LS. The first supporting portion 231 may be formed within, i.e., as part of the compensation layer 210.

The integrated circuit layers 100 may include “first layers,” identified by reference numeral 101 and second layers identified by reference numeral 103. The first layers 101 and the second layers 103, are alternately stacked on top of each other, i.e., the layers are interleaved.

The first layer 101 may be an insulating interlayer made of a metal oxide, silicon oxide or other appropriate material. etc. The second layer 103 may be a conductive material, which may have an etch selectivity different from an etch selectivity of the material comprising the first layer 101. For example, the second layer 103 may be a nitride.

The integrated circuit 10 may include a plurality of charge-trapping structures CTS not shown in FIGS. 1A-1C as well as a channel structure 110, best seen in FIG. 1C. The charge-trapping structures CTS and the channel structure 110 may be “stacked” in a third direction, i.e., a z-direction, on top of a first surface, F1, of the structure LS. The charge-trapping structure CTS may be located on an inner wall of vertical holes 120 formed through the layers 101, 103 of the integrated circuit 10 and may include a gate oxide layer GO, a charge-trapping layer CT and a tunnel oxide layer TO.

The charge-trapping layer CT, which is located between the gate oxide layer GO and the tunnel oxide layer TO, may include a nitride. The gate oxide layer GO may include a high-k material having a dielectric constant higher than SiO₂ for an insulation.

The channel structure 110 may include a channel layer 111 and a core 113. The channel layer 111 may be polysilicon formed in a central, cylindrical portion of the tunnel oxide layer TO, which is the inner-most layer of the charge-trapping structure CTS. The core 113 may be formed by forming oxide as a core dielectric function in a central portion of the channel layer 111.

The integrated circuit 10 may include a plurality of slit trenches 120 configured to divide a semiconductor memory block along a second direction, i.e., a y-direction of the structure LS.

The layers 101, 103 of the integrated circuit 10 may include a cavity layer 105 formed by etching a second layer 103 through the slit trench 120.

The compensation layer 210, best seen in FIG. 1A and FIG. 1B, may be formed on the second surface F2 of the structure LS. The compensation layer 210 may compensate compressive force and tensile force exerted on the integrated circuit 10 and its layers 100, which may be caused by the deposition and removal of different materials on the layers 100 of the integrated circuit 10. The material deposited on or removed from the layers of the integrated circuit 10 may include a conductive material or an insulation material.

Mechanical stress on the layers 101, 103 of the integrated circuit 10 and the strain produced on those layers by stress, may be generated simply by depositing material on and removing material from the layers 101, 103 during fabrication of the integrated circuit 10 but also by different thermal expansion characteristics of the deposited and removed materials vis-à-vis the thermal expansion characteristics of the materials from which the layers 101 and 103 are formed. Therefore, a deposited conductive layer, a deposited insulating layer, and the cavity layer 105 formed by removing the conductive layer or the insulation layer may each correspond to a stress layer. And for claim construction purposes, a “stress layer” is considered herein as one or more of the layers 101, 103 or 105, which individually or in combination with another layer, generates compressive or tensile stress in the layer itself as well as in other layers 101, 103, 105 of the integrated circuit 10.

Conductive material generating stress may include tungsten, titanium, nitride titanium, molybdenum, cobalt, nickel, etc. Insulative material generating the stress may include Si₃N₄, SiO₂, polysilicon, etc.

The compensation layer 210 may include a stress-compensation material, which provides a stress force, which opposes stress induced by at least one or more material deposited on or removed from one or more of the layers 101, 103 of the integrated circuit layers 100. The material that causes stress to the structure may be a material only deposited on, only removed from, or both deposited on and removed from the integrated circuit layers 100. When the stress is compressive, the material of the compensation layer 210 induces an opposing tensile force. When the stress is tensile, the material of the compensation layer 210 induces an opposing compressive force.

The stress compensation material may include a material for providing an opposing stress, i.e., an induced compensating stress, the magnitude of which is substantially the same as or at least similar to the magnitude of the stress induced by the material deposited onto or removed from a layer 101,103 but which is induced in a direction that is opposite to the stress induced by the deposited and removed materials. The stress compensation material may include either a conductive material or an insulating material, which is deposited on or removed from the integrated circuit layers 100. The conductive stress compensation material may include tungsten, titanium, nitride titanium, molybdenum, cobalt, nickel, etc. The insulating stress compensation material may include Si₃N₄, SiO₂, polysilicon, etc. The compensation layer 210 may have a thickness, which is selected responsive to wafer deformation-prevention requirements.

Referring to FIGS. 1A and 1B, the first supporting portion 231 may be formed by injecting an oxide filler after forming a support trench 220 in the compensation layer 210. In FIG. 1A, the support trench 220 may be located at or near a geometric center line, CL, of the compensation layer 210 and formed using a mask having a support pattern at the compensation layer 210 and etching away the unmasked portion(s) of the compensation layer 210.

The compensation material may include a material for providing the stress opposite to the stress of the material deposited on or removed from the integrated circuit layers 100 within a set range. As shown in FIG. 1A, the at least one first supporting portion 231 may be extended in the compensation layer along the first direction, i.e., the x-direction substantially perpendicular to the slit trench 120.

The compensation layer 210 may include a material, having mechanical characteristics, e.g., a thermal expansion coefficient, Tc, substantially the same as or at least similar to the mechanical characteristics of material deposited on or removed from the integrated circuit layers 100. The compensation layer 210 may include the compensation material for providing the stress substantially the same as or similar to the stress of the material deposited on or removed from the integrated circuit layers 100 within a set range. As shown in FIG. 1B, the at least one first supporting portion 231 may be extended in the compensation layer 210 along the second direction (y-direction) substantially parallel to the slit trench 120. The set range as a reference for determining the similar stress may have a difference between the stresses of about ±1%, ±5%, ±10%, etc. It is important to note that the trench 220 need not be filled with compensation material. The trench 220 need only be provided with enough compensation material to oppose or counteract stress that may be induced by material deposition and removal processes and thus eliminate or at least reduce the deformation they may cause. Such an amount is referred to herein as being “an effective amount.”

A compensation layer 210 and a first supporting portion 231 may form compensation structures 200a and 200b.

The compensation structures 200a and 200b may compensate stress caused by compressive force or the tensile force, either of which may be generated by the material deposited on or removed from the integrated circuit layers 100, at the second surface F2 of the structure LS.

The first supporting portion 231 may act against the compressive force or the tensile force by the material deposited on or removed from the integrated circuit layers 100 to support the compensation layer 210 and the structure LS, thereby reducing or preventing the deformation of the structure LS.

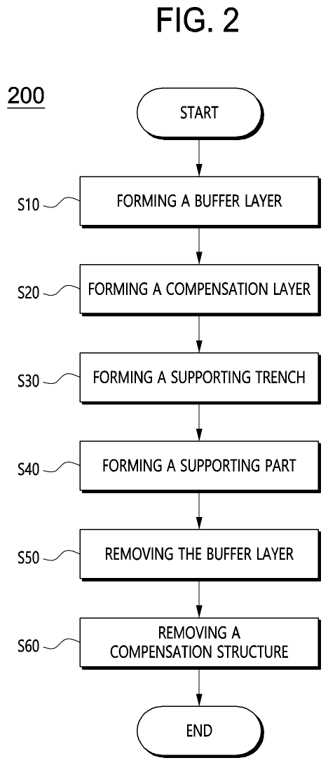

FIG. 2 is a flow chart illustrating a method 200 of manufacturing a semiconductor device in accordance with example embodiments.

Referring to FIG. 2, a method 200 of manufacturing a semiconductor device in accordance with example embodiments may include a step S10 for forming a buffer layer, a step S20 for forming a compensation layer, a step S30 for forming a support trench, a step S40 for forming a support, a step S50 for forming removing the buffer layer and a step S60 for removing a compensation structure. Although not depicted in drawings, the method may further include a step for forming an integrated circuit 10 before forming the buffer layer in step S10.

In step S10, a buffer layer BF may be formed on an exposed upper surface of the integrated circuit 10. The buffer layer BF may protect the integrated circuit 10 in a masking process, a pattern formation process, an etching process or a deposition process for forming the compensation structure 200a and 200b.

The buffering layer BF may be formed before or after the deposition process or the removal process with respect to the integrated circuit 10. For example, in manufacturing a NAND memory device, the buffer layer BF may be formed before or after a deposition process or a removal process performed after forming the slit trench 120 for dividing the semiconductor memory block.

The buffer layer BF may include a material such as oxide or nitride having bad coverage. The material of the buffer layer BF may form an overhang at an opened upper end of a slit or a hole in the deposition process to cover the slit or the hole.

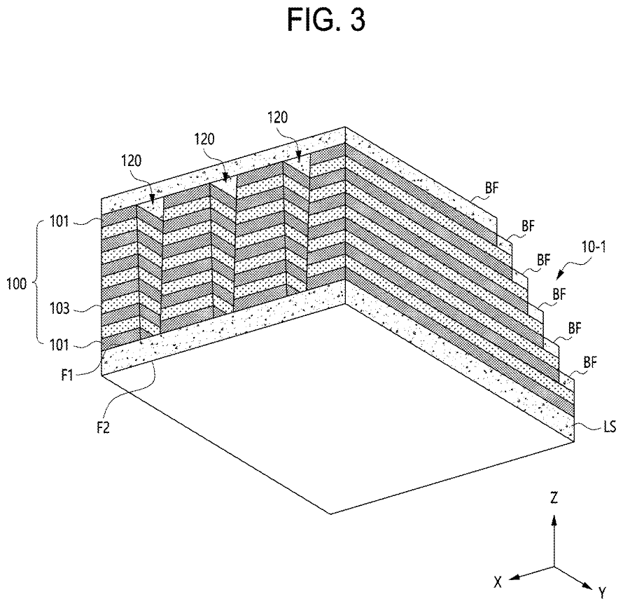

FIG. 3 is a perspective view of an integrated circuit 10-1, for illustrating step S10, i.e., forming a buffer layer before removing a second layer.

Referring to FIG. 2 and FIG. 3, the buffer layer, BF, may be formed on various layers, and in particular conductive layers 103 as shown.

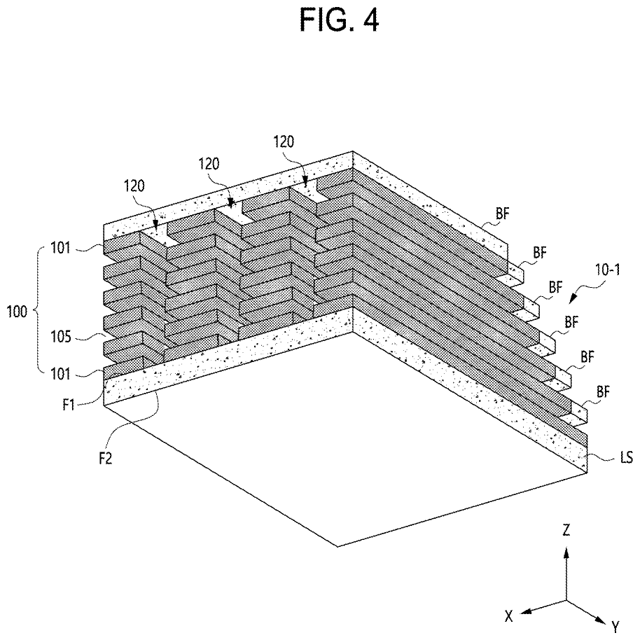

FIG. 4 is a perspective view illustrating step S10 for forming a buffer layer after removing a second layer.

Referring to FIG. 2 and FIG. 4, the buffer layer, BF, may be formed after forming the cavity layer 105, which is formed by removing the second layer 103. The second layer 103 may be removed by an etching process through the slit trenches 120. The etching process may include a wet etching process using an etchant for remaining the first layer 101 and selectively removing the second layer 103.

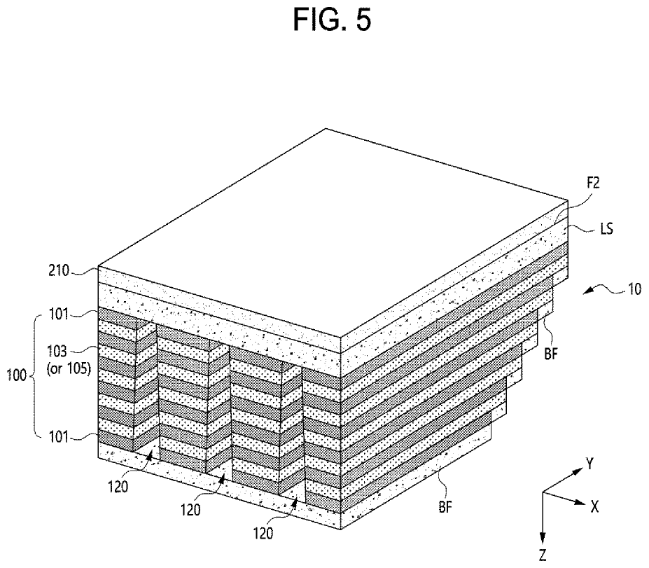

A process for forming the compensation structure 200a and removing the buffer layer BF before removing the second layer 103 may be illustrated with reference to FIGS. 5 to 12B. However, a method of example embodiments may include forming the compensation structure 200a after removing the second layer 103 and removing the buffer layer BF. Thus, the same reference numerals may refer to the same elements.

FIG. 5 is a perspective view for illustrating step S20, i.e., forming a compensation layer in accordance with example embodiments.

Referring to FIG. 2 and FIG. 5, the compensation layer 210 may be formed on the second surface F2 of the structure LS. The integrated circuit 10 may be formed on the structure LS.

Alternatively, the compensation layer 210 may be formed before forming the integrated circuit 10.

The compensation layer 210 may reduce or prevent the warpage, which is referred to herein as warpage.

In example embodiments, the compensation layer 210 may include a compensation material.

The compensation material may include a material for providing the stress substantially the same as or similar to the stress of the material deposited on or removed from the integrated circuit 10 within a set range.

The compensation material may include a material for providing a stress opposite to the stress of the material deposited on or removed from the integrated circuit 10.

The compensation material may include tungsten, titanium, nitride titanium, molybdenum, cobalt, nickel, Si₃N₄, SiO₂, polysilicon, a combination thereof, etc.

The compensation layer 210 may be formed before removing the second layer 103. Alternatively, the compensation layer 210 may be formed after removing the second layer 103.

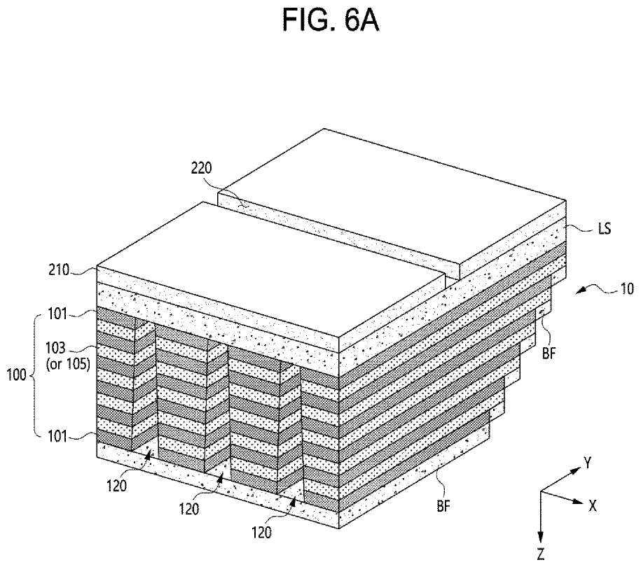

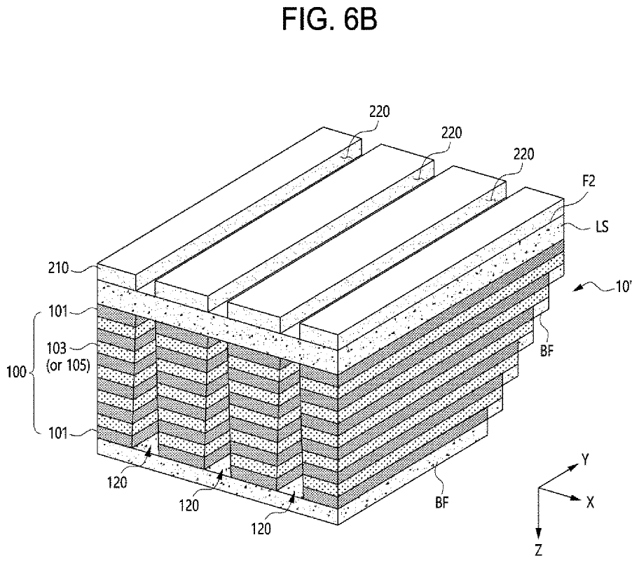

FIGS. 6A and 6B are views illustrating step S30 for forming a support trench in accordance with example embodiments.

Referring to FIGS. 6A and 6B, the at least one support trench 220 as a stress layer may be formed at the compensation layer 210. The support trench 220 may be formed by forming a mask on the compensation layer 210 and etching the compensation layer 210 using the mask.

The compensation layer 210 may include the compensation material for providing a stress opposite to the stress of the material deposited on or removed from the structure LS. As shown in FIG. 6A, the at least one support trench 220 may be extended in the first direction (x-direction) substantially vertical to the slit trench 120.

The compensation layer 210 may include the compensation material for providing a compensating stress, i.e., a stress the magnitude of which is substantially the same as or similar to the stress of the material deposited on or removed from the integrated circuit 10 but in the opposite or a nearly opposite direction. As shown in FIG. 6B, the at least one support trench 220 may be extended in the second direction (y-direction) parallel, or substantially parallel to the slit trench 120.

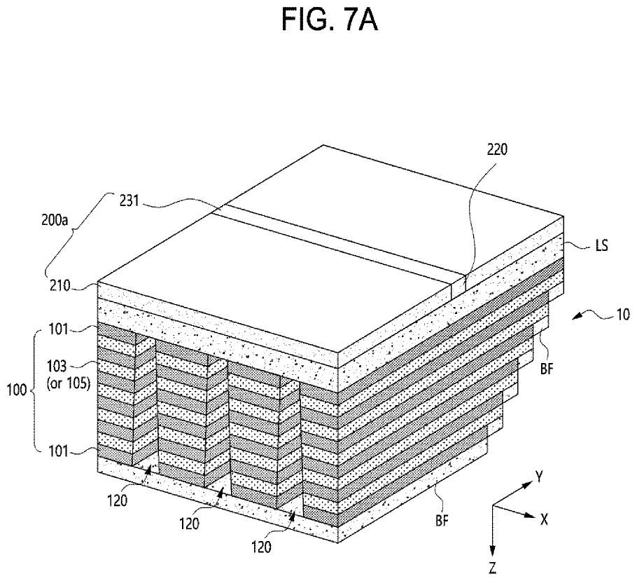

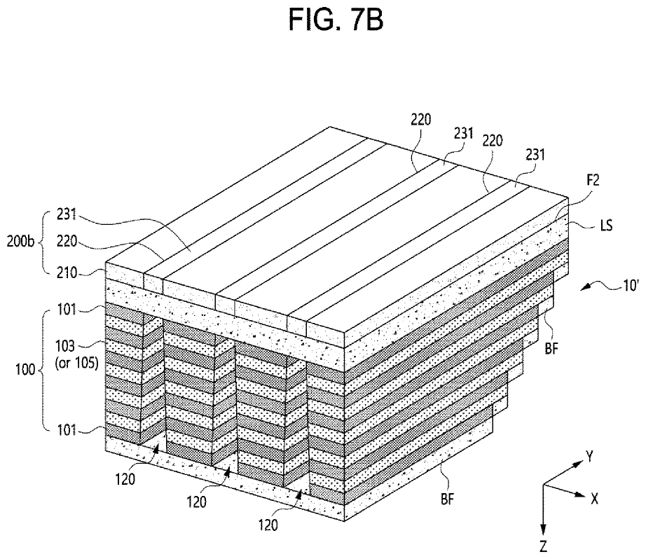

FIGS. 7A and 7B are views illustrating step S40 of FIG. 2, for forming a support with a first supporting portion in accordance with example embodiments.

After forming the support trench 220, a supporting material as a filler may be deposited or injected into the support trench 220 to form the first supporting portion 231, thereby forming the compensation structure 200a and 200b. The supporting material may include an oxide such as silicon oxide. The first supporting portion 231 may oppose stress generated at the structure LS and thus reduce deformation of the integrated circuit 10.

The first supporting portion 231 may have various shapes configured to reduce or prevent warpage.

The compensation structure 200a and 200b may be planarized by a chemical mechanical polishing (CMP) process to control a thickness of the compensation structure 200a and 200b.

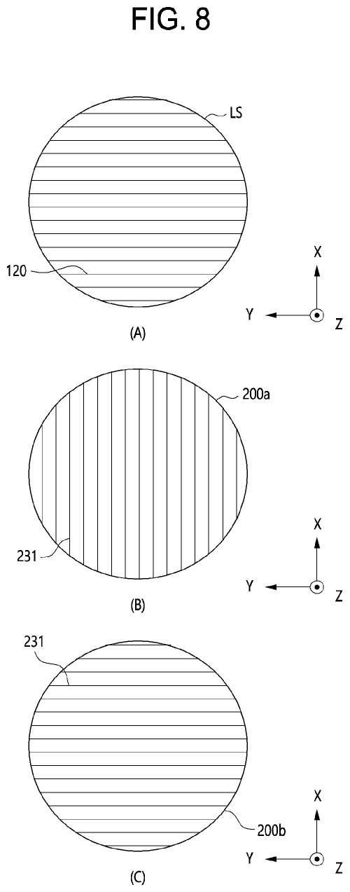

FIG. 8 is a view illustrating a slit trench on a front surface of a structure LS with a compensation layer and a first supporting portion on a second surface of the structure LS in accordance with example embodiments.

Referring to FIG. 8A, the slit trench 120 may be extended in the second direction (y-direction) of the structure LS and may divide the memory block.

Referring to FIG. 8B, the at least one supporting portion 231 may be extended on a surface of the compensation structure 200a along the first direction (x-direction) of the structure LS substantially perpendicular to the slit trench 120.

Referring to FIG. 8C, the at least one supporting portion 231 may be extended on a surface of the compensation structure 200b along the second direction (y-direction) of the structure LS substantially parallel to the slit trench 120 configured to divide the semiconductor memory block.

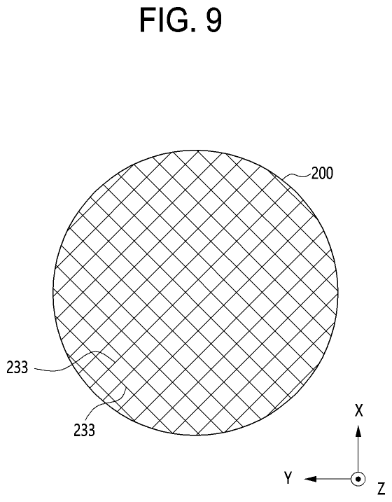

FIG. 9 is a view illustrating a slant support in accordance with example embodiments.

Referring to FIG. 9, an at least one second supporting portion 233 may be extended in a direction intersected with the first direction or the second direction of the structure LS.

For example, the second supporting portion 233 may be extended on the surfaces of the compensation structure 200a and 200b along the direction intersected with the slit trench 120 in FIG. 8A configured to divide the semiconductor memory block.

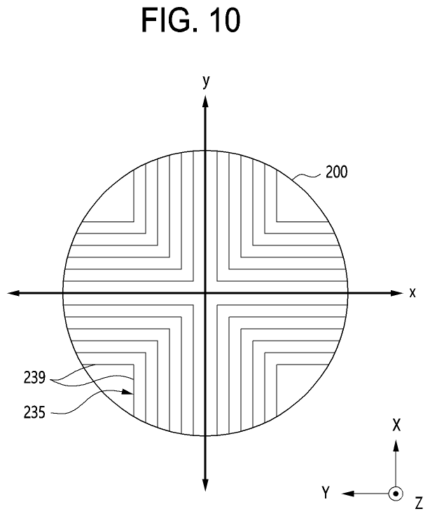

FIG. 10 is a view illustrating a support in accordance with example embodiments.

Referring to FIG. 10, a plurality of third supporting portions 235 may be extended on the surfaces of the compensation structure 200a and 200b along the first direction (x-direction) and the second direction (y-direction), which may be substantially perpendicular to each other to divide the second surface F2 of the structure LS into the four regions. The third supporting portion 235 may include extensions 239. The extensions 239 may be substantially parallel to the first and second directions. Thus, the extensions 239 may be substantially perpendicular to each other. The extensions 239 may be arranged from the first and second directions. The extensions 239 may be spaced apart from each other by a uniform gap. The third supporting portions 235 may be placed in each of the four regions of the second surface F2 of the structure LS.

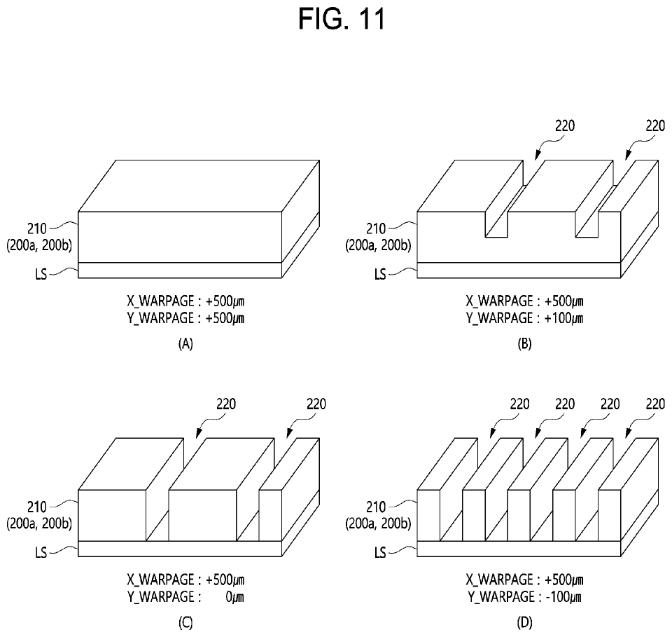

FIGS. 11A and 11B are perspective views of a semiconductor structure illustrating how the warpage can change the size of a device responsive to a support trench depth and the number of support trenches.

FIG. 11A illustrates that warpage of the lower structure LS without the supporting trench 220 may be about +500 μm in the x-direction and about +500 μm in the y-direction.

FIG. 11B illustrates that two supporting trenches 220 having a shallow depth may change the warpage in the y-direction into about +100 μm in the y-direction. In contrast, the warpage in the x-direction may be still about +500 μm.

FIG. 11C illustrates that two widely separated supporting trenches 220 having a depth that extends down to the structure LS may change the warpage in the y-direction into about 0 μm in the y-direction. In contrast, the warpage in the x-direction may be still about +500 μm.

FIG. 11D illustrates that two supporting trenches 220 having a depth to the structure LS may change the warpage in the y-direction into about −100 μm in the y-direction. In contrast, the warpage in the x-direction may be still about +500 μm.

Stress applied to the structure LS may therefore be controlled by supporting portions 231, 233 and 235 formed by injecting or depositing a supporting material into the supporting trenches 220 in FIGS. 11A to 11D.

Although not depicted in drawings, the warpage caused by compressive force may be controlled by horizontally forming the supporting trenches 220 in the slit trench 120 of the integrated circuit 10 and by controlling a depth and a number of the supporting trench 220.

According to example embodiments, the stress applied to the structure LS may be controlled by controlling the direction, the depth and the number of the supporting trench 220 or the supporting portion 231, 233 and 235. Thus, the size and the direction of the warpage of the structure LS may be controlled.

The stress may be generated at the structure LS by changing the material or the structure of the integrated circuit 10 on the structure LS. The change of the material or the structure in the integrated circuit 10 may generate the difference between the compressive forces or the tensile forces applied to the structure LS and the integrated circuit 10. The compensation structure 200a may be formed on the second surface F2 of the structure LS to compensate the stress applied to the structure LS so that the warpage may be reduced or prevented.

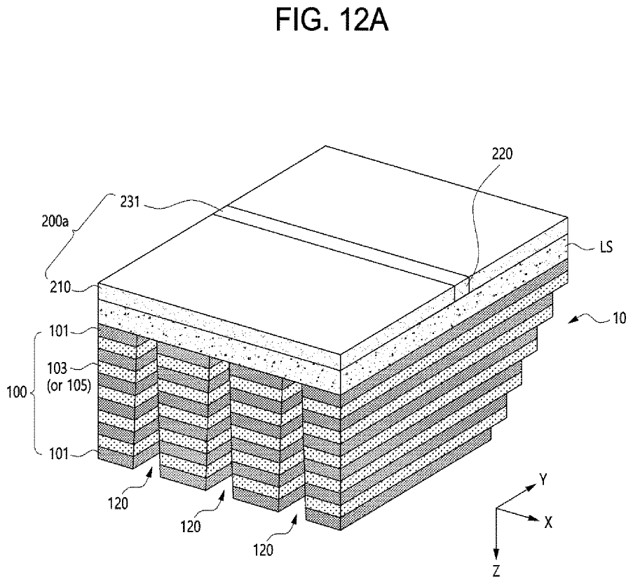

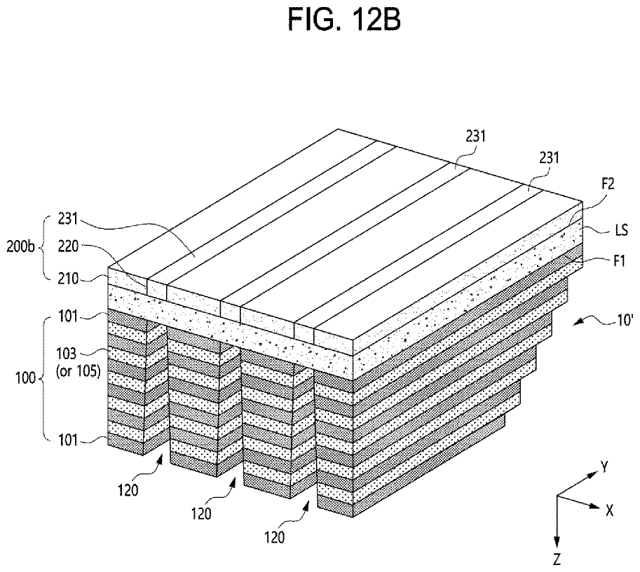

FIGS. 12A and 12B are views illustrating step S50 for removing a buffer layer.

Referring to FIGS. 12A and 12B, after forming the compensation structure 200a and 200b, the buffer layer BF may be removed for a following process. The buffer layer BF may be removed by a CMP process and a cleaning process.

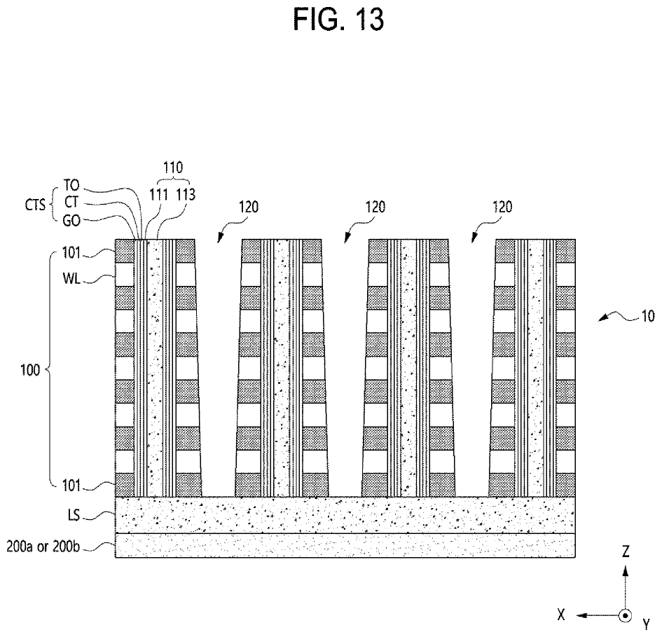

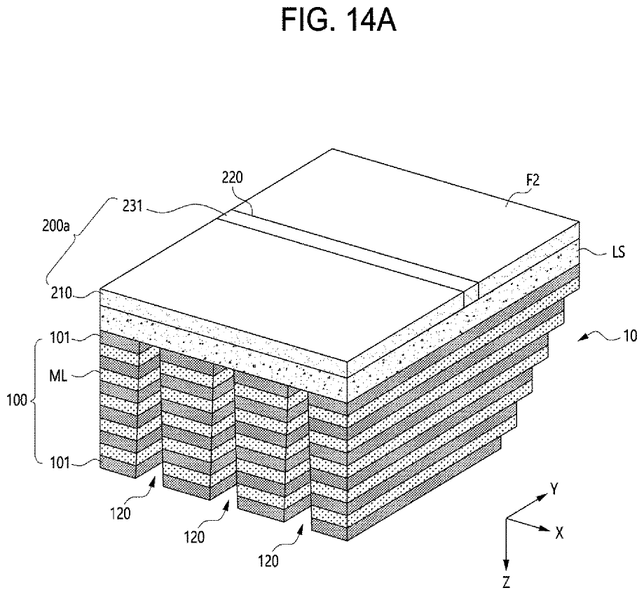

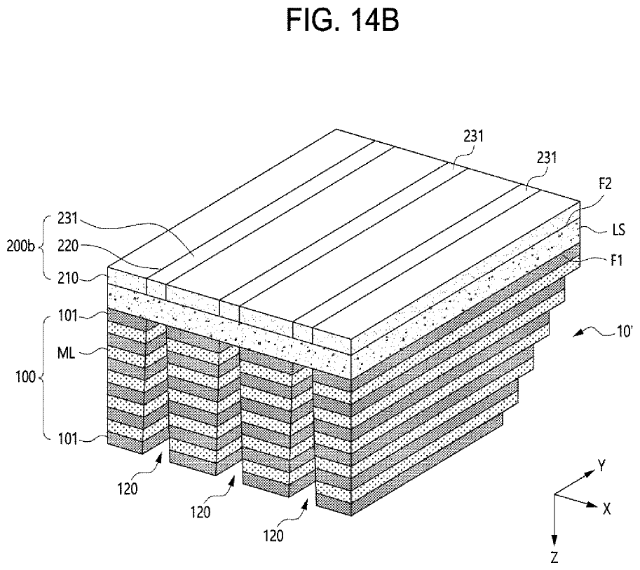

FIGS. 13, 14A and 14B are views illustrating a structure LS and an integrated circuit 10 with a memory cell structure layer at a second layer by a following process after removing a buffer layer.

After removing the buffer layer BF, the second layer 103 may be selectively removed by an etch process through the slit trenches 120 to form the cavity layer 105.

After forming the cavity layer 105, a deposition process may be performed through the slit trench 120 to form a conductive layer WL in the cavity layer 105. The conductive layer WL may include a word line including tungsten. Thus, a memory cell structure layer ML may be formed.

The memory cell structure layer MA may include a memory cell structure and the word line. The memory cell structure may include an oxide layer, a charge-trapping layer and oxide layer sequentially stacked. For example, the memory cell structure may have an oxide-nitride-oxide (ONO) structure.

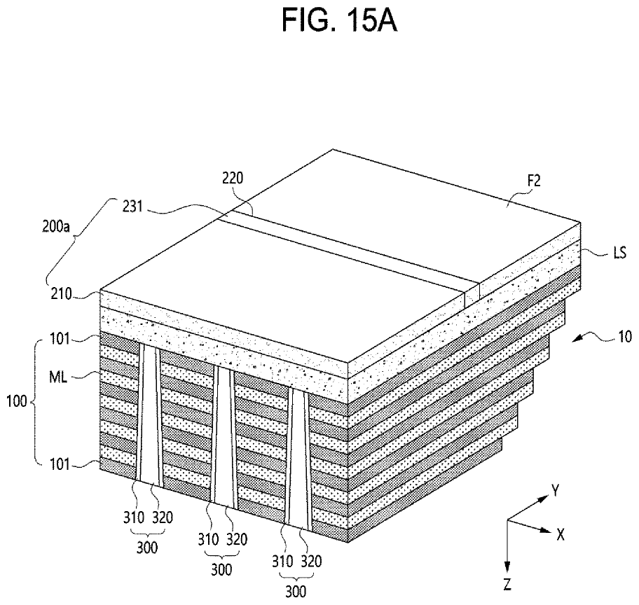

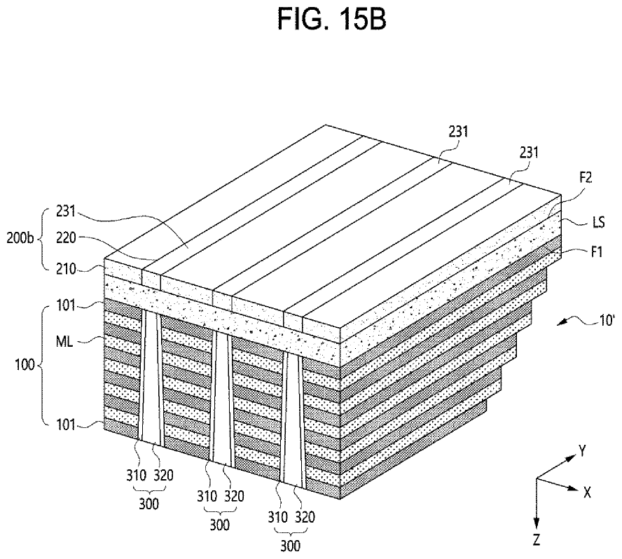

FIGS. 15A and 15B are views illustrating an integrated circuit and a structure with a slit in accordance with example embodiments.

After forming the memory cell structure layer ML, as shown in FIGS. 15A and 15B, a slit 300 may be formed at the slit trench 120. The slit 300 may be formed by forming a slit insulation layer 310 on an inner wall of the slit trench 120 and forming a conductive material in the slit insulation layer 310 to form a slit conductive layer 320.

After forming the slit 300, the step S60 may be performed to remove the compensation structure.

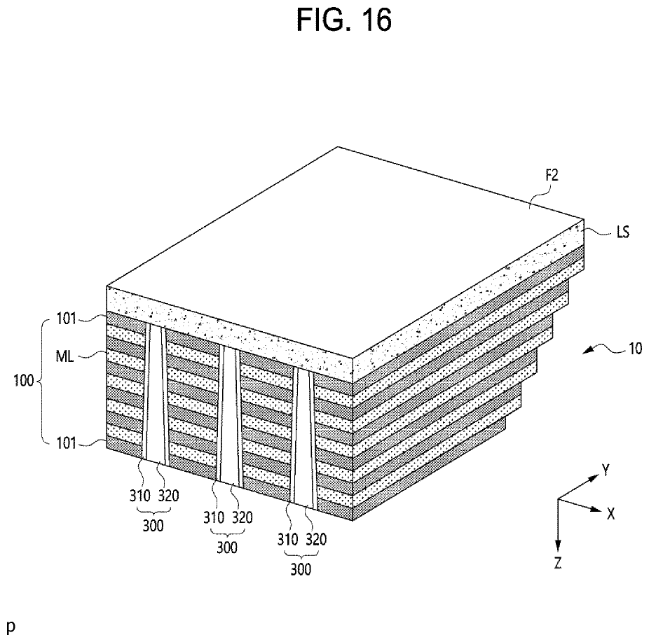

FIG. 16 is a view illustrating a structure after removing a compensation layer and an integrated circuit with a slit.

Referring to FIG. 16, the compensation structure 200a or 200b may be removed from the second surface F2 of the structure LS. The compensation structure 200a or 200b may be removed by a CMP process, an oxide cleaning process, a nitride strip process, etc.

The removal of the compensation structure 200a or 200b may be selectively performed in a random following process after forming the compensation structure 200a or 200b.

For example, the removal of the compensation structure 200a or 200b may be performed before packaging the semiconductor device. Further, the removal of the compensation structure 200a or 200b may be selectively performed when the warpage may not be generated at the structure LS.

In example embodiments, the semiconductor device may be a non-volatile memory device but is not limited thereto.

According to example embodiments, the compensation structure may be formed on the “bottom” surface of the structure including a wafer in order to compensate for stress caused by different compressive forces or the tensile forces applied to the structure. The warpage may thus be reduced or prevented in the semiconductor fabrication process. Semiconductor device defects may be decreased to improve the yield of the semiconductor device manufacturing process.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. A method of manufacturing a semiconductor device, the method comprising:
providing a structure having a first surface and a second surface opposite to the first surface; and
forming a compensation layer over the second surface of the structure, which includes a support trench, into which is provided an effective amount of compensation material, mechanical characteristics of which oppose stress induced in into the structure, from the second surface of the structure.

2. The method of claim 1, wherein the compensation material is a material which provides a force to the structure, that opposes force applied to the structure by the first surface.

3. The method of claim 1, wherein the compensation material is a material which provides a stress to the structure, which has a magnitude that is substantially the same as the magnitude of stress induced in the structure from the first surface.

4. The method of claim 1, further comprising forming at least one support in the compensation layer, after forming the compensation layer.

5. The method of claim 4, wherein the at least one support is extended in a first direction of the structure.

6. The method of claim 4, wherein the at least one support is extended in a second direction of the structure.

7. The method of claim 4, wherein the at least one support is extended in a direction intersected with a first direction or a second direction of the structure.

8. The method of claim 4, wherein the at least one support is extended in a first direction and a second direction substantially perpendicular to each other to divide the second surface of the structure into four regions.

9. The method of claim 1, further comprising forming an integrated circuit over the first surface of the structure.

10. The method of claim 9, wherein the integrated circuit comprises a stress generating layer.

11. The method of claim 10, further comprising the step of forming at least support extended in the compensation layer along a direction substantially vertical to the at least one stress layer.

12. The method of claim 10, wherein the compensation material is a material which provides a stress having a direction opposite to the direction of the stress induced in the structure by at least one material deposited over or removed from the integrated circuit to form the at least one stress layer.

13. The method of claim 10, further comprising forming at least support extended in the compensation layer along a direction substantially horizontal to the at least one stress layer.

14. The method of claim 13, wherein the compensation material provides a stress substantially the same as or similar to the stress within a set range the stress of a material deposited over or removed from the integrated circuit to form the at least one stress layer.

15. The method of claim 9, further comprising forming a buffer layer over the integrated circuit before forming the compensation layer.

16. The method of claim 15, further comprising:
forming at least one support extended in the compensation layer; and
removing the buffer layer.

17. The method of claim 16, further comprising removing the compensation layer and the support.

18. The method of claim 1, wherein the compensation layer comprises at least one of a supporting trench or a support crossing the compensation layer, and a size of the stress is controlled by controlling at least one of a direction and a number of the supporting trench or the support.
